(19) United States
(12) Patent Application Publication
(10) Pub. No.: US 2013/0051048 A1
(43) Pub. Date: Feb. 28, 2013

(54) LIGHT HEAD WITH PHOSPHOR IMPREGNATED LIGHT OPTIC AND METHOD

(71) Applicant: Paul L. Stein, O'Fallon, MO (US)

(72) Inventor: Paul L. Stein, O'Fallon, MO (US)

(73) Assignee: CODE 3, INC., St. Louis, MO (US)

(21) Appl. No.: 13/593,003

(22) Filed: Aug. 23, 2012

Related U.S. Application Data
(60) Provisional application No. 61/527,401, filed on Aug. 25, 2011.

(51) Int. Cl. F21V 13/08; F21V 13/14; H05K 13/00; B60Q 1/00

(52) U.S. Cl. 362/510; 362/260; 362/235; 29/592.1

(57) ABSTRACT

A light head for a light bar and/or an emergency vehicle light includes a light mixer with diffuse reflectivity, a blue light engine and a phosphor impregnated light optic. Blue light from the light engine causes the phosphor to fluoresce and emit colored light having a wavelength different that the wavelength of blue light of the light engine.

### BACKGROUND

The invention relates to light heads for an emergency vehicle light, such as a light bar, which can be manufactured, configured and assembled in various configurations. In particular, the invention relates to light heads having a phosphor impregnated light optic which emits different colored light and which are interchangeable.

Conventionally, white LED lights have been implemented by using a blue LED device coated with a phosphor. The blue LED emits blue light which is converted to white light by its phosphor coating.

### SUMMARY

According to one example of the invention, a light head including blue LEDs are arranged in combination with a phosphor impregnated light optic in order to perform with uniform luminance for use as an emergency vehicle light.

In one exemplary form, a light head for a light bar and/or an emergency vehicle light comprises a light mixer having an interior surface providing diffuse reflectivity, a light engine and a phosphor impregnated light optic located over the light mixer for receiving the reflected light from the light mixer and for receiving the emitted light from the light engine.

In one exemplary form, the invention includes a method of assembling a light head comprising:
providing a light mixer having an interior surface providing diffuse reflectivity;
providing a light engine including an LED and LED driver components for energizing the LED to emit light have a particular wavelength, said light engine located adjacent the interior surface of the light mixer and emitting light at least some of which is reflected by the light mixer;
selecting a phosphor impregnated light optic from a plurality of light optics, each of the plurality of light optics having a phosphor which when illuminated by light of a particular wavelength emits light having a wavelength different than the particular wavelength wherein each light optic has a different phosphor than the other light optics; and
positioning the selected light optic over the light mixer for receiving the reflected light from the light mixer and for receiving the emitted light from the LED, which received light causes the phosphor to fluoresce and emit light having a wavelength different that the particular wavelength, said light optic including a beam forming device for providing a beam the emitted light.

In one exemplary form, the invention includes a method of assembling an emergency vehicle light by providing first and second light heads as follows:
providing first and second light mixers, each having an interior surface providing diffuse reflectivity;
providing first and second light engines, each including an LED and LED driver components for energizing the LED to emit light have a particular wavelength, said first and second light engines located adjacent the interior surface of the first and second light mixer, respectively, and emitting light at least some of which is reflected by their respective light mixer;
providing a plurality of optics, each of the plurality of optics having a phosphor which when illuminated by light of a particular wavelength emits light having a wavelength different than the particular wavelength wherein at least some of the optics have a different phosphor than the other optics;
selecting a first phosphor impregnated light optic having a first phosphor from a plurality of optics;
assembling the first light head by locating the selected first optic over the first light mixer for receiving the reflected light from the first light mixer and for receiving the emitted light from its LED, which received light causes the first phosphor to fluoresce and emit light having a wavelength different that the particular wavelength, said first optic including a beam forming device for forming the light emitted by the first phosphor into a first beam;
selecting a second phosphor impregnated light optic having a second phosphor from a plurality of optics; and
assembling the second light head by locating the selected second optic over the second light mixer for receiving the reflected light from the second light mixer and for receiving the emitted light from its LED, which received light causes the second phosphor to fluoresce and emit light having a wavelength different that the particular wavelength, said second optic including a beam forming device for forming the light emitted by the second phosphor into a second beam.
   The provided first and second light heads are affixed to a provided emergency vehicle light housing to form a light bar.

### BRIEF DESCRIPTION OF THE DRAWINGS

FIG. 1 is an exploded, perspective illustration of one example of a light head of the invention.

FIG. 2 is a vertical, cross-sectional illustration of the light head of FIG. 1 with its components assembled.

FIGS. 3-5 are vertical, cross-sectional, perspective illustrations of a light head of the invention wherein the light mixer is a trough having flat sides and curved sides in at least some of the corners and wherein the diffuser and beam forming device in the form of a collimator are shown in phantom.

FIG. 6 is an illustration of one example of an emergency vehicle light in the form of a light bar of the invention and/or one example of a light bar kit of the invention.

FIG. 7 is a vertical, cross-sectional illustration of a light head of the invention wherein the beam forming device is a combination of a convex lens and trough having stepped, flat sides.

FIG. 8 is a sectional view of FIG. 7 taken along lines 8-8.

FIG. 9 is a graph illustrating the relative spectral power distribution of various examples of phosphor impregnated light diffusers of the invention with relative radiant power (%) along the y-axis and wavelength (nm) along the x-axis.

FIG. 10 is a polar graph showing the intensity distribution of the examples of phosphor impregnated light diffusers of the invention graphed in FIG. 7.

### DETAILED DESCRIPTION

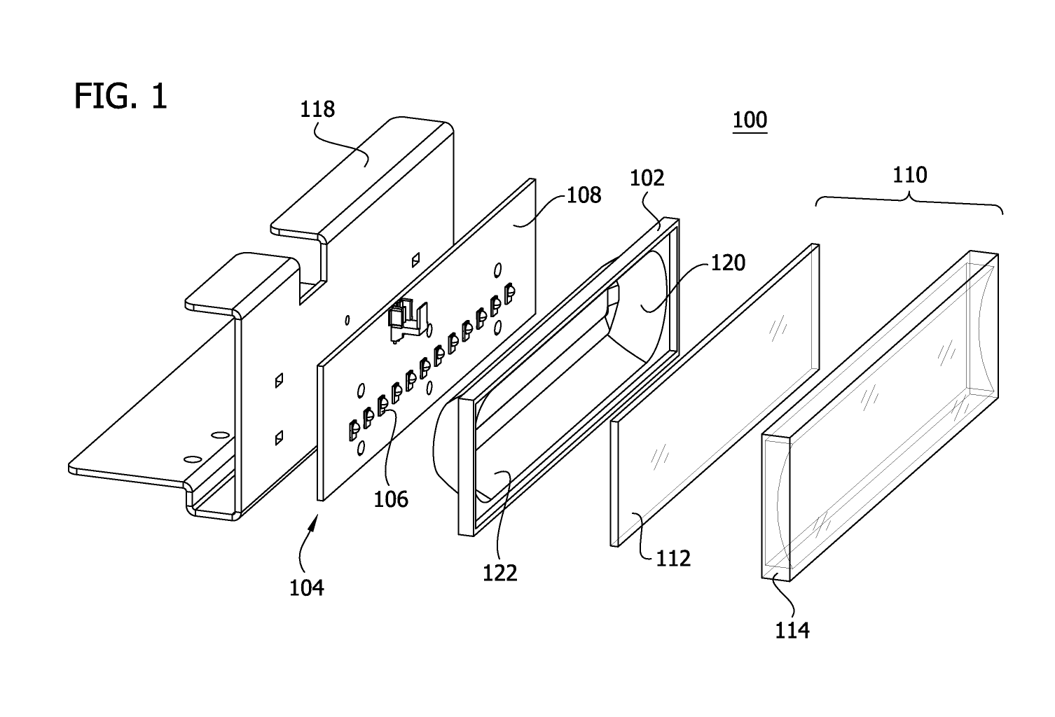

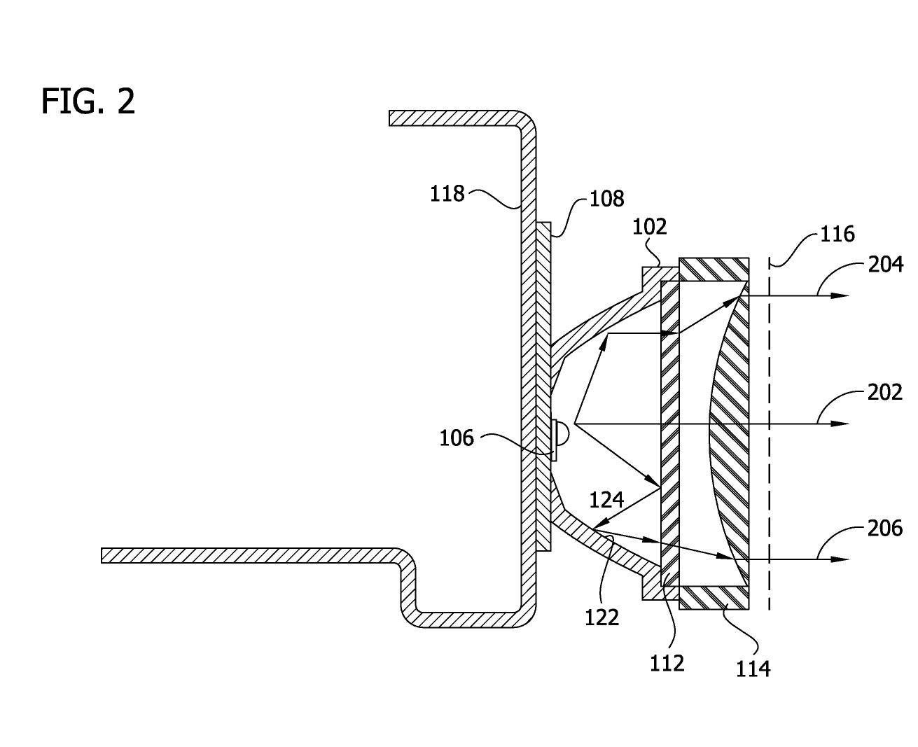

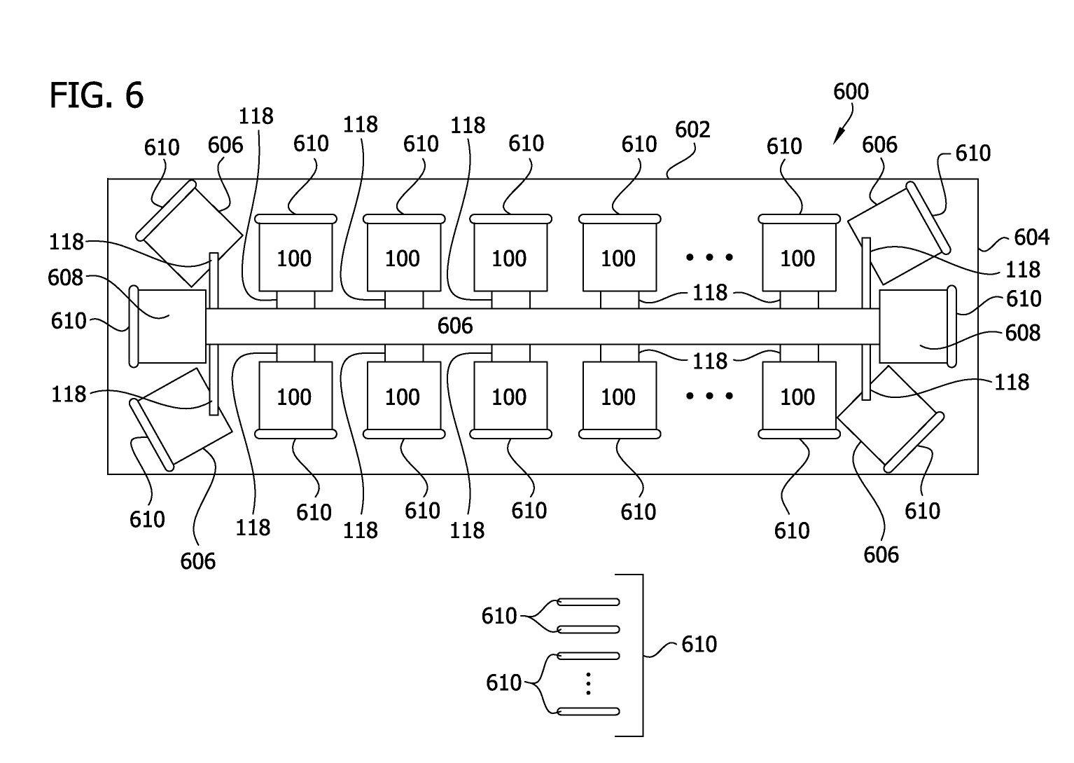

FIG. 1 is an exploded, perspective illustration of one example of a light head 100 of the invention. FIG. 2 is a vertical, cross-sectional illustration of the light head 100 of FIG. 1 with its components assembled. It is contemplated that the light head 100 is configured for use as part of a light bar (see FIG. 6) and/or any emergency vehicle light, including any light on a vehicle for providing an indication of the vehicle's position or movement (frequently referred to as a warning signal). The light head 100 includes a light mixer 102 having one or more interior surfaces providing diffuse reflectivity. A coating may be on the interior surface of the mixer 102 to provide or enhance the diffuse reflectivity. A light engine 104 includes one or more LEDs 106 (light emitting diodes) and LED driver components mounted on a circuit board 108 for energizing the LED to emit light have a particular wavelength. The light engine 104 is located within the light mixer 102 and adjacent the light mixer 102 in order to emit light, at least some of which is reflected by and mixed by the light mixer 102 and at least some of which directed outwardly from the mixer 102. For example, the light mixer 102 has surfaces and coating which cause light emitted by the light engine 104 to be blended into an integrated, diffuse output of light.

The light output is directed to a phosphor impregnated light optic 110 located over the light mixer 102 for receiving the reflected output light from the light mixer 102 and for receiving the light directly emitted from the LEDs 106. The light received by the light optic 110 causes the phosphor impregnated in the light optic 110 to fluoresce and emit light having a wavelength different that the particular wavelength of light emitted by the LEDs. The optic 110 includes a beam forming device for forming the light emitted by the phosphor into a beam of light for signaling an observer remote from a vehicle having the light head 100 mounted thereon. In one example, the phosphor impregnated in the light optic 110 may be a coating applied to a transparent or translucent substrate.

As an example of one form, the optic 110 comprises a phosphor impregnated light diffuser 112 in combination with a collimator 114 as the beam forming device. The phosphor impregnated light diffuser 112 is located over the light mixer for receiving the reflected output light from the light mixer 102 and for receiving the light directly emitted from the LEDs 106. The received light causes the phosphor to fluoresce and emit light having a wavelength different that the particular wavelength. The collimator 114 collimates the light emitted by the light diffuser to create a beam of light for signaling an observer remote from a vehicle having the light head 100 mounted thereon. FIGS. 1-5 illustrate the collimator 114 over the light diffuser 112, which is immediately adjacent to the light mixer 102.

Although most phosphor-impregnated light diffusers 112 have phosphors which produce a narrow band of colored light, it may be desirable in one embodiment to filter the produced light. As an example in this regard, the light diffuser 112 and/or the collimator 114 may be comprised of a light filtering material which transmits a desired color light and which absorbs light of other colors. If red or yellow light output is desired from the light head 100, the diffuser 112 and/or the collimator 114 may be configured of a red or yellow substrate which transmits red or yellow light and which absorbs light of other colors. More specifically, if the phosphor of the light diffuser 112 emits red or yellow light when illuminated by the light from the LEDs 106, the diffuser 112 and/or the collimator 114 may be configured of a red or yellow substrate to filter the output light within a certain bandwidth of the red or yellow spectrum. As another example, the light mixer 102 may be comprised of a light filtering material which reflects a desired color light and which absorbs light of other colors.

Alternatively, an optional light filter 116 (see FIG. 2) may be positioned adjacent the light optic 110 for transmitting light of a desired color and for absorbing light of other colors. The filter 116 may also be located between the light optic 110 and the light mixer 102. Also, the light mixer 102 may have a coating or material which filters the light output.

FIG. 2 illustrates some exemplary light rays which form a part of the light output of the light engine 100. Some light rays 202 emitted by the LEDs 106 are directed toward and through the light optic 110. Other light rays 204 are reflected by the light mixer 102 and then are directed toward and through the light optic 110. Other light rays 206 are reflected by the light optic 110, then reflected by the light mixer 102 and then are directed toward and through the light optic 110. Some light may also be reflected by both the light mixer 102, then reflected by the light optic 110 and then reflected again by before being directed toward and through the light optic 110.

Light rays represented by the arrows 202, 204 are reflected to pass through the light diffuser 112 and light rays 204 are directly emitted to pass through the light diffuser 112, causing the phosphor to fluoresce and convert the light from one wavelength to another wavelength. Light rays represented by the arrows 206 are reflected back for further phosphor conversion. The total result provides up to 30% greater light output than a similar phosphor coated LED die (based on white color data).

In FIG. 2, the collimator 114 is illustrated as a convex lens for generating a substantially, horizontally flat light output. However, it is contemplated that the collimator 114 may be any lens as desired to shape the light output beam. Alternatively or in addition, the diffuser 112 may have beam shaping characteristics (e.g., convex). Also, in embodiments in which the diffuser 112 and collimator 114 are combined into one element, the element may have beam shaping characteristics. In FIG. 1, a corner of collimator 114 has been cut away to illustrate a plano-convex lens shape. The collimator may be configured to provide light output having a flood pattern, a spot pattern, a fan pattern or some other desired pattern for vehicle lighting. In some embodiments, an air space is located between the diffuser 112 and the collimator 114.

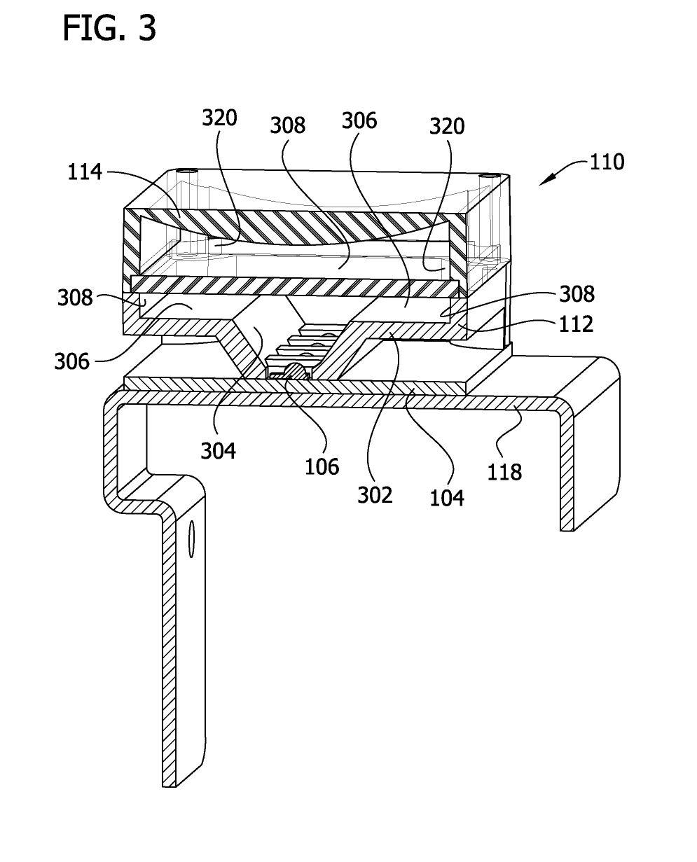

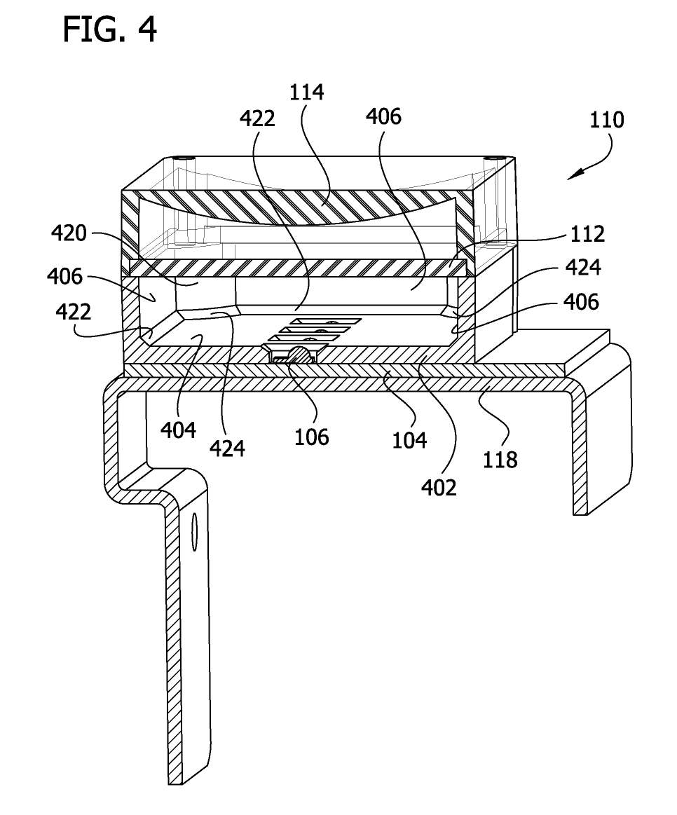

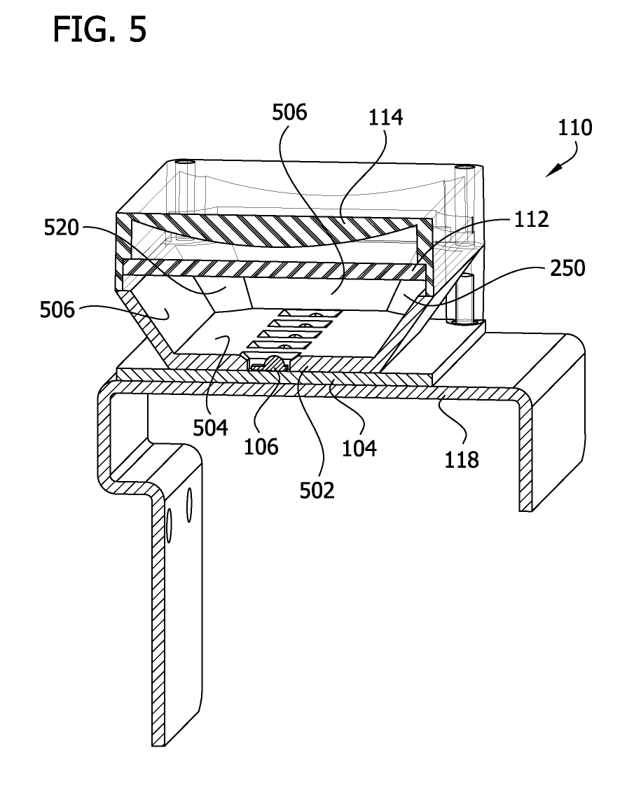

As illustrated in FIGS. 1-5, the light mixer 102, 302, 402, 502 comprises one or more surfaces. In FIGS. 1-2, the light mixer 110 includes curved end surfaces 120, side surfaces 122 which may be curved or flat and beveled surfaces 124, which may also be curved or flat. It is also contemplated that one or more of the surfaces of the light mixer 102, 302, 402, 502 may be a partial cylindrical reflective surface 320, 420, as shown in FIGS. 3 and 4. It is also contemplated that one or more of the surfaces of the light mixer 102, 302, 402, 502 may be a partial conical surface 520 as shown in FIG. 5. It is also contemplated that one or more of the surfaces of the light mixer 102, 302, 402, 502 may be a partial spherical surface (not shown). Alternatively or in addition, the light mixer may be a trough having curved and/or flat sides, a parabolic reflective surface having curved and/or flat sides, or an elliptical reflective surface having curved and/or flat sides.

As illustrated in FIGS. 1-5, the light engine 104 may comprise a linear array of a plurality of LEDs 106 such that the LED driver components on the board 108 energize the linear array. In some forms, a single LED may be part of the light engine 104. In some forms, the light engine 104 may have two or more LEDs in any two or three dimensional pattern or configuration.

In one form, the light mixer 102 comprises a mixing chamber coated with a highly diffuse reflectance material (e.g., CerFlex TECH supplied by CerFlex, MC-PET supplied by Furukawa, White 97 supplied by WhiteOptics, PolarKote supplied by Light Beam, Valar supplied by Genesis, and/or ePTFE Diffuse Reflector Product supplied by W.L. Gore). In one form, the collimator 114 comprises a clear polycarbonate lens (e.g., plano-convex lens.

FIGS. 3-5 are vertical, cross-sectional, perspective illustrations of a light head of the invention wherein the light mixer is a trough having flat sides and curved sides in at least some of the corners and wherein the diffuser and beam forming device are shown in phantom. In FIG. 3, the light mixer 302 includes a V-shaped depression 304 in which the LEDs are positioned, flat surfaces 306, flat surfaces 308 perpendicular to surface 306, and curved surfaces 320. In FIG. 4, the light mixer 402 includes flat surfaces 404, flat surfaces 406, curved surfaces 420, beveled flat surfaces 422 and beveled curved surfaces 424. In FIG. 5, the light mixer 502 includes flat surfaces 504, slanted flat surfaces 506, and slanted curved surfaces 520

As used herein, a curved surface includes but is not limited to a parabolic, elliptical, and/or spherical surfaces and a combination thereof with or without a flat surface, such as a beveled surface. It is contemplated that a beveled surface may be used to transition between any two surfaces which meet. It is also contemplated that all or part of any of the light mixer 102 surfaces may be coated with a high diffuse reflectance material and/or a highly reflective, mirrored surface.

In one form, the light optic 110 may be a single, unitary, integrated combination of the light diffuser 112 and the collimator 114, such as phosphor impregnated polycarbonate plano-convex lens impregnated with a phosphor.

FIG. 6 is an illustration of one example of an emergency vehicle light in the form of a light bar 600 comprising a plurality of the light heads 100 and a housing 602 for receiving the plurality of light heads 100. In one form the housing 602 comprises one or more lenses 604 (e.g., upper and lower lenses) mounted to a base 606 for supporting the housing 602 and the light heads 100. For example, the base 606 may be an extruded aluminum support. It is also contemplated that an optional heat sink, such as a support 118 (e.g., a bracket) may be connected to the light heads 100 in heat transfer relationship to dissipate heat generated by the light heads 100 when the light engines 104 are energized. The support 118 may engage the base 606 to support the light heads 100 within the light bar 602. As shown in exemplary form in FIGS. 1-5, the support 118 may in heat transfer relation to the circuit board 108 dissipate heat generated by the light heads 100 when the light engines 104 are energized. In some exemplary embodiments, the light bar 602 may include light heads 100 configured as take-down lights 606 and configured as alley lights 608. Each of the light heads 100, 606, 608 includes a light optic 610.

FIG. 6 is also illustrates one example of a light bar kit of the invention. A light bar kit comprises the light bar 602 and a plurality 612 of additional phosphor impregnated light optics 610 which are interchangeable with the phosphor impregnated light optics 610 of the light heads 100 in the light bar 600.

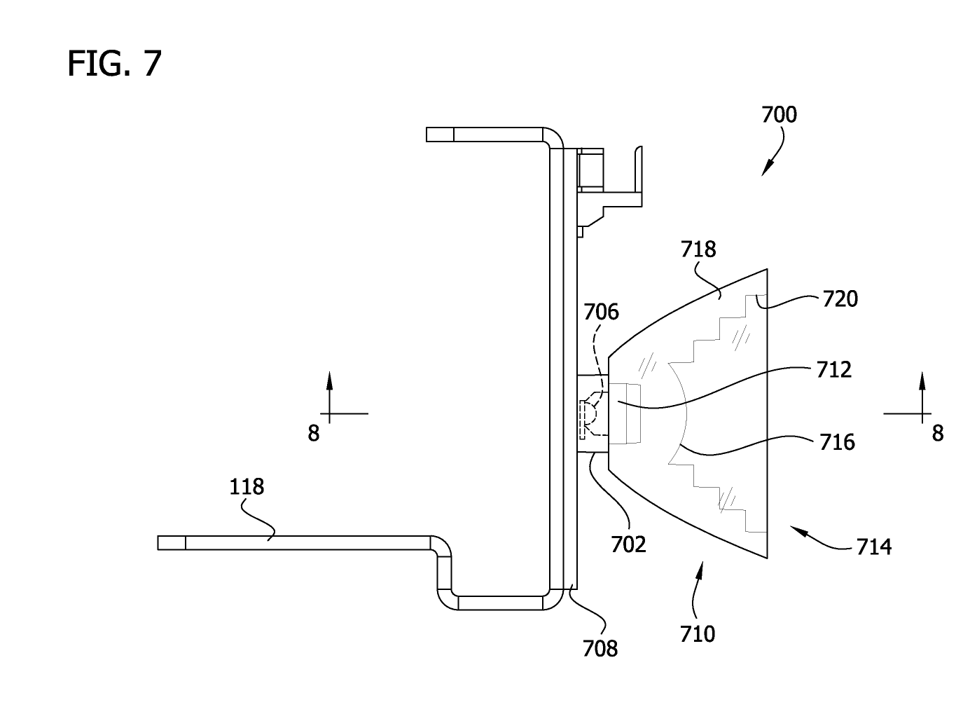

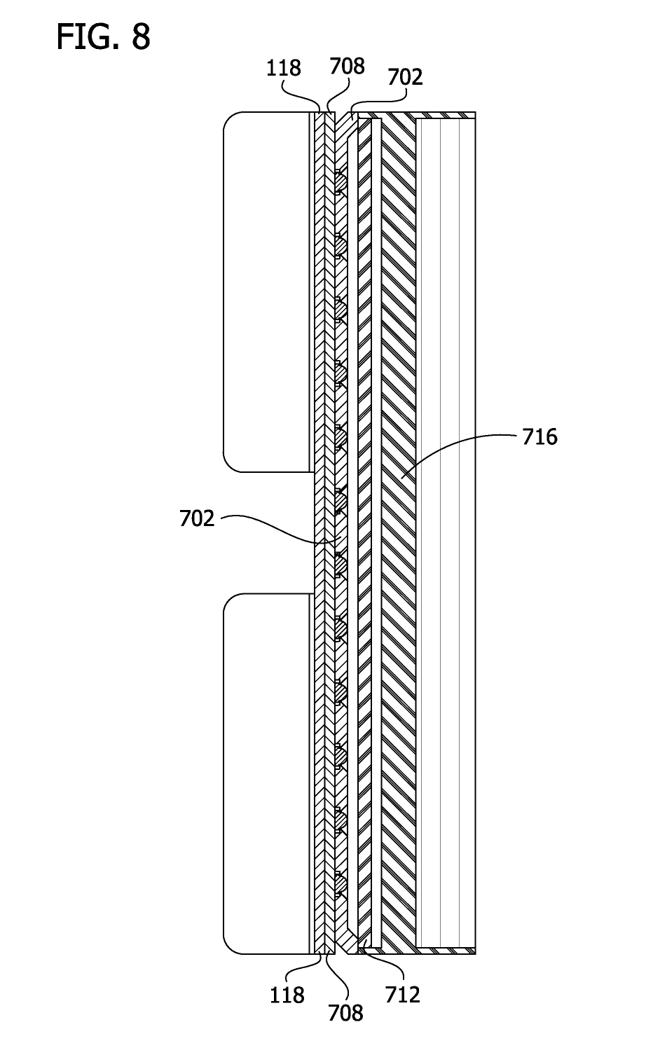

FIG. 7 is a vertical, cross-sectional illustration of a light head 700 of the invention wherein the beam forming device is a convex lens in combination with a integral trough having stepped, flat sides. FIG. 8 is a sectional view of FIG. 7 taken along lines 8-8. The light head 700 includes a light mixer 702 having one or more interior surfaces providing diffuse reflectivity. A coating may be on the interior surface of the mixer 702 to provide or enhance the diffuse reflectivity. A light engine includes one or more LEDs 706 (light emitting diodes) and LED driver components mounted on a circuit board 708 for energizing the LEDs to emit light have a particular wavelength. The light engine is located within the light mixer 702 and adjacent the light mixer 702 in order to emit light, at least some of which is reflected by and mixed by the light mixer 702 and at least some of which directed outwardly from the mixer 702. For example, the light mixer 702 has surfaces or a surface coating which cause light emitted by the light engine to be blended into an integrated, diffuse output of light.

The light output is directed to a phosphor impregnated light optic 710 located over the light mixer 702 for receiving the reflected output light from the light mixer 702 and for receiving the light directly emitted from the LEDs 706. The light received by the light optic 710 causes the phosphor impregnated in the light optic 710 to fluoresce and emit light having a wavelength different that the particular wavelength of light emitted by the LEDs. The optic 710 includes a beam forming device for forming the light emitted by the phosphor into a beam of light for signaling an observer remote from a vehicle having the light head 700 mounted thereon. In one example, the phosphor impregnated in the light optic 710 may be a coating applied to a transparent or translucent substrate.

As an example of one form, the optic 710 comprises a phosphor impregnated light diffuser 712 in combination with a collimator 714 as the beam forming device. The phosphor impregnated light diffuser 712 is located over the light mixer for receiving the reflected output light from the light mixer 702 and for receiving the light directly emitted from the LEDs 706. The received light causes the phosphor to fluoresce and emit light having a wavelength different that the particular wavelength. The collimator 714 includes a convex lens 716 and a trough 718 which collimate the light emitted by the light diffuser to create a beam of light for signaling an observer remote from a vehicle having the light head 700 mounted thereon. In one form, the trough 718 is formed integrally with the lens 716 and includes stepped, flat sides 720 approximating a parabolic or elliptical configuration as shown in FIG. 7. The lens 716 and trough 718 together form a beam of light from the light emitted by the phosphor of the diffuser 712.

### Method of Assembling a Light Head

The invention in one exemplary form comprises a method of assembling a light head 100 such as illustrated in FIGS. 1-5. The light mixer 102 is provided with an interior surface with diffuse reflectivity. The light engine 104 including LEDs 106 and LED driver components 108 is provided for energizing the LEDs 106 to emit light have a particular wavelength. The light engine 104 is located adjacent the interior surface of the light mixer 102 for emitting light at least some of which is reflected by the light mixer 102. A phosphor impregnated light optic 110 is selected from a plurality of light optics 110 wherein each of the plurality of light optics 110 has a phosphor which when illuminated by light of a particular wavelength emits light having a wavelength different than the particular wavelength. Each light optic 110 has a different phosphor than the other optics. The selected light optic 110 is positioned over the light mixer 102 for receiving the reflected light from the light mixer 102 and for receiving the emitted light from the LEDs 106. As a result, the received light causes the phosphor to fluoresce and emit light having a wavelength different that the particular wavelength. Optionally, the light optic 110 includes a collimator 114 as the beam forming device for forming into a beam the light emitted by the light diffuser 112 impregnated with the phosphor.

### Method of Assembling an Emergency Vehicle Light

The invention in one exemplary form comprises a method of assembling an emergency vehicle light 600 such as a light bar 602 as illustrated in FIG. 6. First and second light heads are provided by:
a. providing first and second light mixers 102, 302, 402, 502, each having an interior surface providing diffuse reflectivity.
b. providing first and second light engines 104, each including an LED and LED driver components for energizing the LED to emit light having a particular wavelength. The first and second light engines are located adjacent the interior surface of the first and second light mixer, respectively, and emit light at least some of which is reflected by their respective light mixer.
c. providing a plurality of optics, each of the plurality of optics having a phosphor which when illuminated by light of a particular wavelength emits light having a wavelength different than the particular wavelength at least some of the optics have a different phosphor than the other optics.
d. selecting a first phosphor impregnated light optic 110 having a first phosphor from a plurality of optics.
e. assembling the first light head by locating the selected first optic over the first light mixer for receiving the reflected light from the first light mixer and for receiving the emitted light from its LED, which received light causes the first phosphor to fluoresce and emit light having a wavelength different that the particular wavelength. The first optic includes a collimator 114 for collimating the light emitted by the first phosphor.
f. selecting a second phosphor impregnated light optic 110 having a second phosphor from a plurality of optics.
g. assembling the second light head by locating the selected second optic over the second light mixer for receiving the reflected light from the second light mixer and for receiving the emitted light from its LED, which received light causes the second phosphor to fluoresce and emit light having a wavelength different that the particular wavelength. The second optic includes a collimator 114 for collimating the light emitted by the second phosphor.
   The provided first and second light heads 100 are affixed to a provided emergency vehicle light housing 602 to form the light bar 600. For example, a lower lens is affixed to a base, the light heads 100 are affixed to the base and then the upper lens is placed over and affixed to the lower lens to assemble a light bar for use on a vehicle.

FIG. 7 is a graph illustrating the relative spectral power distribution of various examples of phosphor impregnated light diffusers 110 of the invention with relative radiant power (%) along the y-axis and wavelength (nm) along the x-axis.

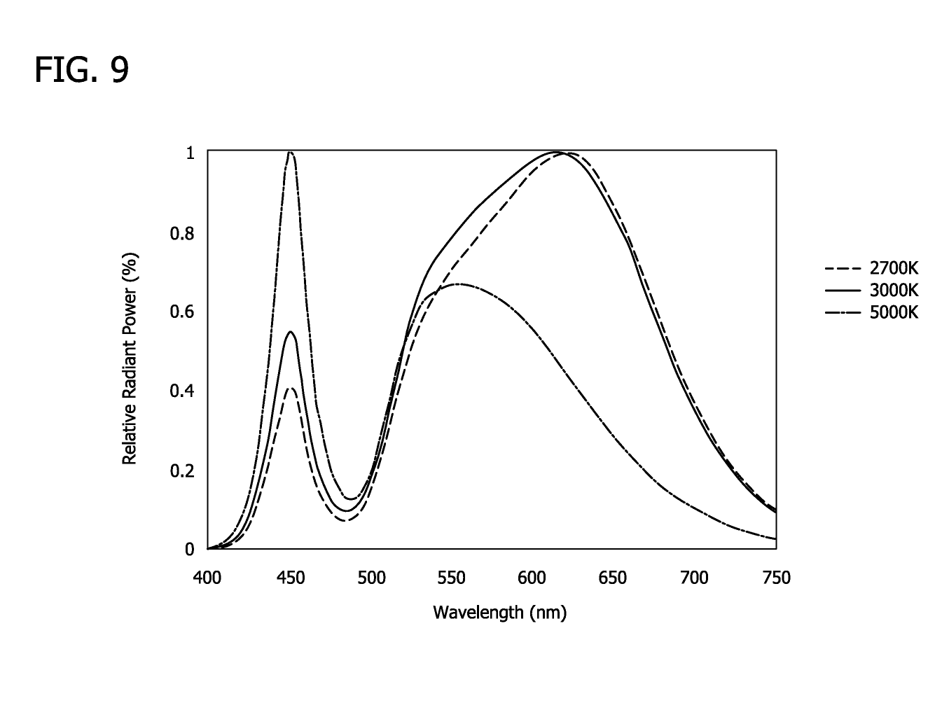

The light diffuser comprises a phosphor impregnated polycarbonate substrate (e.g., supplied by Internatix Chromalit™ Remote Phosphor Light Source). In exemplary forms as illustrated in FIG. 9, the light diffuser when illuminated by the LED light engine emits green light at 5000K having a wavelength in the range of about 520-550 nm, or amber light (not shown in FIG. 9) having a wavelength in the range of about 585-600 nm or red or red/orange light at 3000K having a wavelength in the range of about 615-645 nm. The phosphor fluoresces when energized by the blue light and emits white light and/or light of a different color than the blue light, such as in the range of about 475-750 nm.

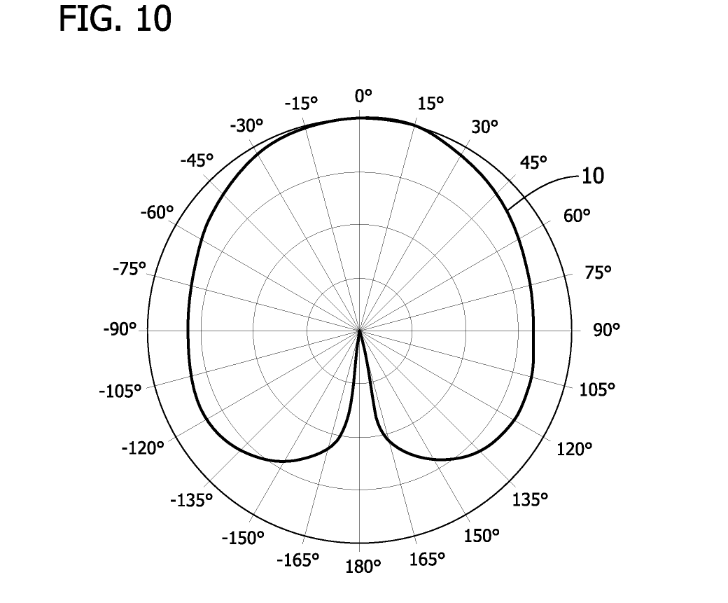

FIG. 10 is a polar graph including line 10 showing the intensity distribution of the examples of phosphor impregnated light diffusers of the invention graphed in FIG. 9.

Accordingly, at least some of the exemplary embodiments provide one or more of the following advantages over using a blue LED coated with a phosphor to produce light of desired color:
Only one type of light engine 104 can be stocked and only one type of light mixer 102 for all types and colors of light heads 100 can be stocked, including take-down lights 606 and alley lights 608.
The light heads 100 are compatible with various blue LEDs from various vendors.
Light output of the light heads 100 is 30% higher for white color compared to prepackaged white LEDs (e.g., blue LEDs having phosphor coatings which fluoresce to produce white light).
Light output of the light heads 100 at 60° off-angle is 50% of zero horizontal and zero vertical as part of light diffuser's diffusion pattern.
The light optic 110 does not tend to change color or fade over time as compared to the prior art.
The light head 100 requires only a change in the light optic 110 or the collimator 114 or the addition of a light filter 116 to adjust the beam and/or color and/or pattern of the light head 100.
The material of the light mixer 102 may be made of a coated substrate (such as aluminum, paper or ceramic), which is capable of withstanding temperatures of 200° C.
All light heads 100 of a light bar or emergency warning light regardless of the color of light it generates can use the same light engine 104 and the same light mixer 102.

In order to achieve different colors of light output from the light heads 100, several options are available. For example as noted above, the light optic 114 may be impregnated with a phosphor which emits the desired color light. As a specific example, if a red or yellow light is desired, a phosphor which when illuminated by blue LEDs (or other color LEDs) and which fluoresces and emits red or yellow light would be used to impregnate the light optic and/or its light diffuser. As another example, the light optic may be may comprise a light filtering material which emits the desired color light and which absorbs light of other colors other than the desired color. As a specific example, if a red or yellow light is desired, the light optic and/or its light diffuser and/or its beam forming device may be made of a polycarbonate which is dyed red or yellow. Alternatively, a filtering material may be placed over the light optic to obtain a desired color. As a specific example, a red or yellow light filter or red or yellow substrate may be placed over the light optic so that red or yellow light is transmitted to an observer and other color light is absorbed by the light filter. In one form, the light diffuser may be a ChromaLit™ phosphor composite manufactured and sold by Internatix Corporation. The light diffuser 110 (phosphor impregnated polycarbonate substrate) may fluoresce to emit red, blue, amber, or white light.

The Abstract and summary are provided to help the reader quickly ascertain the nature of the technical disclosure. They are submitted with the understanding that they will not be used to interpret or limit the scope or meaning of the claims. The summary is provided to introduce a selection of concepts in simplified form that are further described in the Detailed Description. The summary is not intended to identify key features or essential features of the claimed subject matter, nor is it intended to be used as an aid in determining the claimed subject matter.

The order of execution or performance of the operations in embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

When introducing elements of aspects of the invention or the embodiments thereof, the articles “a,” “an,” “the,” and “said” are intended to mean that there are one or more of the elements. The terms “comprising,” “including,” and “having” are intended to be inclusive and mean that there may be additional elements other than the listed elements.

In view of the above, it will be seen that several advantages of the invention are achieved and other advantageous results attained.

Not all of the depicted components illustrated or described may be required. In addition, some implementations and embodiments may include additional components. Variations in the arrangement and type of the components may be made without departing from the spirit or scope of the claims as set forth herein. Additional, different or fewer components may be provided and components may be combined. Alternatively or in addition, a component may be implemented by several components.

The above description illustrates the invention by way of example and not by way of limitation. This description enables one skilled in the art to make and use the invention, and describes several embodiments, adaptations, variations, alternatives and uses of the invention, including what is presently believed to be the best mode of carrying out the invention. Additionally, it is to be understood that the invention is not limited in its application to the details of construction and the arrangement of components set forth in the following description or illustrated in the drawings. The invention is capable of other embodiments and of being practiced or carried out in various ways. Also, it will be understood that the phraseology and terminology used herein is for the purpose of description and should not be regarded as limiting.

Having described aspects of the invention in detail, it will be apparent that modifications and variations are possible without departing from the scope of aspects of the invention as defined in the appended claims. It is contemplated that various changes could be made in the above constructions, products, and methods without departing from the scope of aspects of the invention. In the preceding specification, various preferred embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

What is claimed is:

1. A light head for a light bar and/or an emergency vehicle light comprising:
a light mixer having an interior surface providing diffuse reflectivity;
a light engine including an LED and LED driver components for energizing the LED to emit light have a particular wavelength, said light engine located adjacent the interior surface of the light mixer and emitting light at least some of which is reflected by the light mixer;
a phosphor impregnated light optic located over the light mixer for receiving the reflected light from the light mixer and for receiving the emitted light from the LED, which received light causes the phosphor to fluoresce and emit light having a wavelength different that the particular wavelength, said optic including a beam forming device for forming a beam of the emitted light.

2. The light head of claim 1 wherein the optic comprises:
a phosphor impregnated light diffuser located over the light mixer for receiving the reflected light from the light mixer and for receiving the emitted light from the LED, which received light causes the phosphor to fluoresce and emit light having a wavelength different that the particular wavelength; and
a lens for forming the light emitted by the light diffuser into the beam.

3. The light head of claim 2 wherein the light diffuser and/or the beam forming device comprises a light filtering material which emits a desired color light and which absorbs light of other colors.

4. A light bar comprising a plurality of the light heads of claim 1, a housing for receiving the plurality of light heads, and a base for supporting the housing and the light heads.

5. A light bar kit comprising the light bar of claim 4 and additional phosphor impregnated optics which are interchangeable with the phosphor impregnated light optic located over the light mixer.

6. The light head of claim 1 wherein the LED when energized by the LED driver components emits blue light having a wavelength in the range of about 425-475 nm and wherein the phosphor fluoresces when energized by the blue light emits light in the range of about 475-750 nm.

7. The light head of claim 1 wherein the light mixer comprises a plurality of interior surfaces, at least one of the interior surfaces comprising a parabolic reflective surface, an elliptical reflective surface, a partial spherical reflective surface and/or a flat reflective surface, and/or wherein the light mixer comprises a trough having curved and/or flat sides.

8. The light head of claim 1 wherein the light engine comprises a linear array of a plurality of LEDs and wherein the LED driver components energize the linear array.

9. An emergency vehicle light comprising a plurality of the light heads of claim 1 and a housing for receiving the plurality of light heads.

10. The light head of claim 1 at least one of the following:
wherein the light optic comprises a light filtering material which emits a desired color light and which absorbs light of other colors; and
further comprising a light filter adjacent the light optic for transmitting light of a desired color and for absorbing light of other colors.

11. The light head of claim 1 wherein the light mixer comprises at least one of the following:
a parabolic reflector;
an elliptical reflector;
a trough;
a reflector having flat surfaces;
a reflector having curved surfaces;
a reflector having partially cylindrical surfaces.

12. A method of assembling a light head comprising:
providing a light mixer having an interior surface providing diffuse reflectivity;
providing a light engine including an LED and LED driver components for energizing the LED to emit light have a particular wavelength, said light engine located adjacent the interior surface of the light mixer and emitting light at least some of which is reflected by the light mixer;
selecting a phosphor impregnated light optic from a plurality of light optics, each of the plurality of light optics having a phosphor which when illuminated by light of a particular wavelength emits light having a wavelength different than the particular wavelength wherein each light optic has a different phosphor than the other light optics; and
positioning the selected light optic over the light mixer for receiving the reflected light from the light mixer and for receiving the emitted light from the LED, which received light causes the phosphor to fluoresce and emit light having a wavelength different that the particular wavelength, said light optic including a beam forming device for forming the emitted light into a beam.

13. The method of claim 12 wherein the optic comprises:
a phosphor impregnated light diffuser located over the light mixer for receiving the reflected light from the light mixer and for receiving the emitted light from the LED, which received light causes the phosphor to fluoresce and emit light having a wavelength different that the particular wavelength; and
a lens for forming the light emitted by the light diffuser into the beam.

14. The method of claim 12 wherein the LED when energized by the LED driver components emits blue light having a wavelength in the range of about 425-475 nm and wherein the phosphor fluoresces when energized by the blue light and emits white light in the range of about 475-750 nm.

15. The method of claim 12 wherein the light mixer comprises a plurality of interior surfaces, at least one of the interior surfaces comprising a parabolic reflective surface, an elliptical reflective surface, a partial spherical reflective surface and/or a flat reflective surface, and/or wherein the light mixer comprises a trough having curved and/or flat sides.

16. A method of assembling an emergency vehicle light comprising:
providing first and second light heads by:
providing first and second light mixers, each having an interior surface providing diffuse reflectivity;
providing first and second light engines, each including an LED and LED driver components for energizing the LED to emit light have a particular wavelength, said first and second light engines located adjacent the interior surface of the first and second light mixer, respectively, and emitting light at least some of which is reflected by their respective light mixer;
providing a plurality of optics, each of the plurality of optics having a phosphor which when illuminated by light of a particular wavelength emits light having a wavelength different than the particular wavelength wherein at least some of the optics have a different phosphor than the other optics;
selecting a first phosphor impregnated light optic having a first phosphor from a plurality of optics;
assembling the first light head by locating the selected first optic over the first light mixer for receiving the reflected light from the first light mixer and for receiving the emitted light from its LED, which received light causes the first phosphor to fluoresce and emit light having a wavelength different that the particular wavelength, said first optic including a first beam forming device for forming the light emitted by the first phosphor into a first beam;
selecting a second phosphor impregnated light optic having a second phosphor from a plurality of optics; and
assembling the second light head by locating the selected second optic over the second light mixer for receiving the reflected light from the second light mixer and for receiving the emitted light from its LED, which received light causes the second phosphor to fluoresce and emit light having a wavelength different that the particular wavelength, said second optic including a second beam forming device for forming the light emitted by the second phosphor into a second beam;
providing an emergency vehicle light housing; and
affixing the provided first and second light heads to the provided emergency vehicle light housing.

17. The method of claim 16 wherein the emergency vehicle light comprises a light bar.

18. The method of claim 16 wherein the optic comprises:
a phosphor impregnated light diffuser located over the light mixer for receiving the reflected light from the light mixer and for receiving the emitted light from the LED, which received light causes the phosphor to fluoresce and emit light having a wavelength different that the particular wavelength; and
a lens for forming the light emitted by the light diffuser into a beam.

19. The method of claim 16 wherein the LED when energized by the LED driver components emits blue light having a wavelength in the range of about 425-475 nm and wherein the phosphor fluoresces when energized by the blue light and emits white light in the range of about 475-750 nm.

20. The method of claim 16 wherein the light mixer comprises a plurality of interior surfaces, at least one of the interior surfaces comprising a parabolic reflective surface, an elliptical reflective surface, a partial spherical reflective surface and/or a flat reflective surface, and/or wherein the light mixer comprises a trough having curved and/or flat sides.
